(19) United States
(12) Patent Application Publication
(10) Pub. No.: US 2012/0174956 A1
(43) Pub. Date: Jul. 12, 2012

(54) Thermoelectric Modules, Thermoelectric Assemblies, and Related Methods

(75) Inventors: Robert Michael Smythe, Cleveland, OH (US); Jeffrey Gerard Hershberger, Shaker Heights, OH (US); Richard F. Hill, Parkman, OH (US)

(73) Assignee: LAIRD TECHNOLOGIES, INC., Earth City, MO (US)

(21) Appl. No.: 13/361,668

(22) Filed: Jan. 30, 2012

Related U.S. Application Data
(63) Continuation-in-part of application No. 12/560,194, filed on Sep. 15, 2009.
Application No. 12/560,194 is a continuation of application No. PCT/US2010/025806, filed on Mar. 1, 2010.
(60) Provisional application No. 61/231,939, filed on Aug. 6, 2009.
(60) Provisional application No. 61/231,939, filed on Aug. 6, 2009.

(51) Int. Cl. H01L 35/32; H01L 35/34

(52) U.S. Cl. 136/230; 136/201; 29/428

(57) ABSTRACT

An example thermoelectric module generally includes a first laminate having a dielectric layer and an electrically conductive layer coupled to the dielectric layer, a second laminate having a dielectric layer and an electrically conductive layer coupled to the dielectric layer, and thermoelectric elements disposed generally between the first and second laminates. At least one of the dielectric layers is a polymeric dielectric layer. The electrically conductive layers of the first and second laminates are at least partially removed to form electrically conductive pads on the respective first and second laminates. The thermoelectric elements are coupled to the electrically conductive pads of the first and second laminates for electrically coupling the thermoelectric elements together. Also disclosed is an exemplary articulated thermoelectric assembly that generally includes rigid upper laminates, thermoelectric elements mechanically and electrically coupled to each upper laminate, and an articulated lower substrate mechanically and electrically coupled to the thermoelectric elements.

### CROSS-REFERENCE TO RELATED APPLICATIONS

This application is a continuation-in-part of U.S. patent application Ser. No. 12/560,194 filed Sep. 15, 2009, which, in turn claims the benefit of U.S. Provisional Patent Application No. 61/231,939 filed Aug. 6, 2009.

This application is also a continuation of PCT International Application No. PCT/US2010/025806 filed Mar. 1, 2010 (now published as WO 2011/016876), which, in turns, claims the benefit of U.S. Provisional Application No. 61/231,939 filed Aug. 6, 2009 and U.S. patent application Ser. No. 12/560,194 filed Sep. 15, 2009.

The entire disclosures of each of the above applications are incorporated herein by reference.

### FIELD

The present disclosure relates generally to thermoelectric modules and assemblies, and to methods for making such thermoelectric modules and assemblies.

### BACKGROUND

This section provides background information related to the present disclosure which is not necessarily prior art.

A thermoelectric module (TEM) is a solid state device that can operate as a heat pump or as an electrical power generator. When a thermoelectric module is used as a heat pump, the thermoelectric module utilizes the Peltier effect to move heat and may then be referred to as a thermoelectric cooler (TEC). When a thermoelectric module is used to generate electricity, the thermoelectric module may be referred to as a thermoelectric generator (TEG). The TEG may be electrically connected to a power storage circuit, such as a battery charger, etc. for storing electricity generated by the TEG.

With regard to use of a thermoelectric module as a TEC, and by way of general background, the Peltier effect refers to the transport of heat that occurs when electrical current passes through a thermoelectric material. Heat is either picked up where electrons enter the material and is deposited where electrons exit the material (as is the case in an N-type thermoelectric material), or heat is deposited where electrons enter the material and is picked up where electrons exit the material (as is the case in a P-type thermoelectric material). As an example, bismuth telluride may be used as a semiconductor material. A TEC is usually constructed by connecting alternating N-type and P-type elements of thermoelectric material (“elements”) electrically in series and mechanically fixing them between two circuit boards, typically constructed from aluminum oxide. The use of an alternating arrangement of N-type and P-type elements causes electricity to flow in one spatial direction in all N-type elements and in the opposite spatial direction in all P-type elements. As a result, when connected to a direct current power source, electrical current causes heat to move from one side of the TEC to the other (e.g., from one circuit board to the other circuit board, etc.). Naturally, this warms one side of the TEC and cools the other side. A typical application exposes the cooler side of the TEC to an object, substance, or environment to be cooled.

### SUMMARY

This section provides a general summary of the disclosure, and is not a comprehensive disclosure of its full scope or all of its features.

Example embodiments of the present disclosure generally relate to thermoelectric modules. In one example embodiment, a thermoelectric module generally includes a first laminate having a polymeric dielectric layer and an electrically conductive layer coupled to the polymeric dielectric layer, a second laminate having a dielectric layer and an electrically conductive layer coupled to the dielectric layer, and thermoelectric elements disposed generally between the first and second laminates. The electrically conductive layer of the first laminate is at least partially removed to form electrically conductive pads on the first laminate. The electrically conductive layer of the second laminate is at least partially removed to form electrically conductive pads on the second laminate. And, the thermoelectric elements are coupled to the electrically conductive pads of the first and second laminates for electrically coupling the thermoelectric elements together.

In another example embodiment, a thermoelectric module generally includes a first laminate having a polymeric dielectric layer, a first electrically conductive layer coupled to the polymeric dielectric layer, and a second electrically conductive layer coupled to the polymeric dielectric layer such that the polymeric dielectric layer is disposed generally between the first and second electrically conductive layers. A second laminate of the thermoelectric module has a polymeric dielectric layer, a first electrically conductive layer coupled to the polymeric dielectric layer, and a second electrically conductive layer coupled to the polymeric dielectric layer such that the polymeric dielectric layer is disposed generally between the first and second electrically conductive layers. Multiple thermoelectric elements are disposed generally between the first and second laminates. The first electrically conductive layer of the first laminate and the first electrically conductive layer of the second laminate are each at least partially removed to form electrically conductive pads on the first and second laminates. The thermoelectric elements are soldered to the electrically conductive pads of the first and second laminates for electrically coupling the thermoelectric elements together.

Example embodiments of the present disclosure also generally relate to methods of making thermoelectric modules. In one example embodiment, a method of making a thermoelectric module generally includes coupling multiple thermoelectric elements to first and second laminates such that the multiple thermoelectric elements are disposed generally between the first and second laminates, wherein the first and second laminates each include an electrically conductive layer coupled to a dielectric layer, and wherein the dielectric layer of the first laminate and/or the dielectric layer of the second laminate is a polymeric dielectric layer, and wherein the multiple thermoelectric elements are coupled to the electrically conductive layers of the first and second laminates.

According to one example embodiment, a thermoelectric assembly includes a plurality of thermoelectric modules. Each of the thermoelectric modules includes a substantially rigid upper laminate, a substantially rigid lower laminate, and a plurality of thermoelectric elements disposed generally between the upper and lower laminates. The assembly also includes a substantially contiguous, substantially rigid, thermally conductive layer. The thermally conductive layer is mechanically connected to each of the thermoelectric modules and scored between adjacent thermoelectric modules to permit the thermally conductive layer to be consistently plastically deformed between adjacent thermoelectric modules.

According to another example embodiment, an articulated thermoelectric assembly includes a plurality of rigid upper laminates and a plurality of thermoelectric elements mechanically and electrically coupled to each upper laminate. The assembly includes an articulated lower substrate. The articulated lower substrate is mechanically and electrically coupled to the thermoelectric elements.

According to another example embodiment, a method of manufacturing an articulated thermoelectric assembly includes forming a plurality of groups of lower conductive pads on a lower substrate. Each group of conductive pads corresponds to a thermoelectric module. The lower substrate includes a dielectric layer and a thermally conductive layer on an opposite face of the dielectric layer from the conductive pads. The method includes scoring the lower substrate between adjacent groups of conductive pads and electrically and mechanically connecting a plurality of thermoelectric elements to each of the groups of lower conductive pads. The method also includes electrically and mechanically connecting a plurality of upper substrates to the thermoelectric elements, each of said upper substrates connected to the thermoelectric elements connected to a different one of said groups of lower conductive pads.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an upper perspective view of an example thermoelectric module including one or more aspects of the present disclosure;

FIG. 2 is a side elevation view of the thermoelectric module of FIG. 1;

FIG. 3 is a plan view of an inner portion of an upper laminate of the thermoelectric module of FIG. 1;

FIG. 4 is an end elevation view of the upper laminate of FIG. 3;

FIG. 5 an upper plan view of another example thermoelectric module including one or more aspects of the present disclosure and defining subcircuits of the thermoelectric module, and illustrating in broken lines some example buried current paths extending from the subcircuits, and the thermoelectric elements included therein, toward a periphery of a lower laminate of the thermoelectric module;

FIG. 6 is a plan view of an inner portion of the lower laminate of the thermoelectric module of FIG. 5 illustrating electrically conductive pads for use in interconnecting the thermoelectric elements of each of the subcircuits;

FIG. 7 is a plan view of an inner portion of an upper laminate of the thermoelectric module of FIG. 5 illustrating electrically conductive pads for use in interconnecting the thermoelectric elements of each of the subcircuits;

FIG. 8 is a section view taken in a plane including line 8-8 in FIG. 5;

FIG. 9 is the section view of FIG. 8 with thermal vias shown installed;

FIG. 10 is a side elevation view of another example thermoelectric module including one or more aspects of the present disclosure;

FIG. 11 is a side elevation view of an example thermoelectric assembly including one or more aspects of the present disclosure;

FIG. 12 is a side elevation view of a portion of the thermoelectric assembly of FIG. 11;

FIG. 13 is a side elevation view of a hinge region of the thermoelectric assembly of FIG. 11;

FIG. 14 is a upper perspective view illustrating the lower laminate of the thermoelectric assembly of FIG. 11; and

FIG. 15 is a lower perspective view illustrating the lower laminate for the thermoelectric assembly of FIG. 11.

### DETAILED DESCRIPTION

Example embodiments will now be described more fully with reference to the accompanying drawings.

With reference now to the drawings, FIGS. 1-4 illustrate an example embodiment of a thermoelectric module (TEM) 100 including one or more aspects of the present disclosure. The illustrated thermoelectric module 100 can be used, for example, as a heat pump, an electrical power generator, etc. in electrical devices such as, for example, computers, etc., as desired. And, as will be described in more detail hereinafter, the illustrated thermoelectric module 100 provides heat transfer capabilities within the electrical devices as well as electrical insulation to circuits included as part of the thermoelectric module 100.

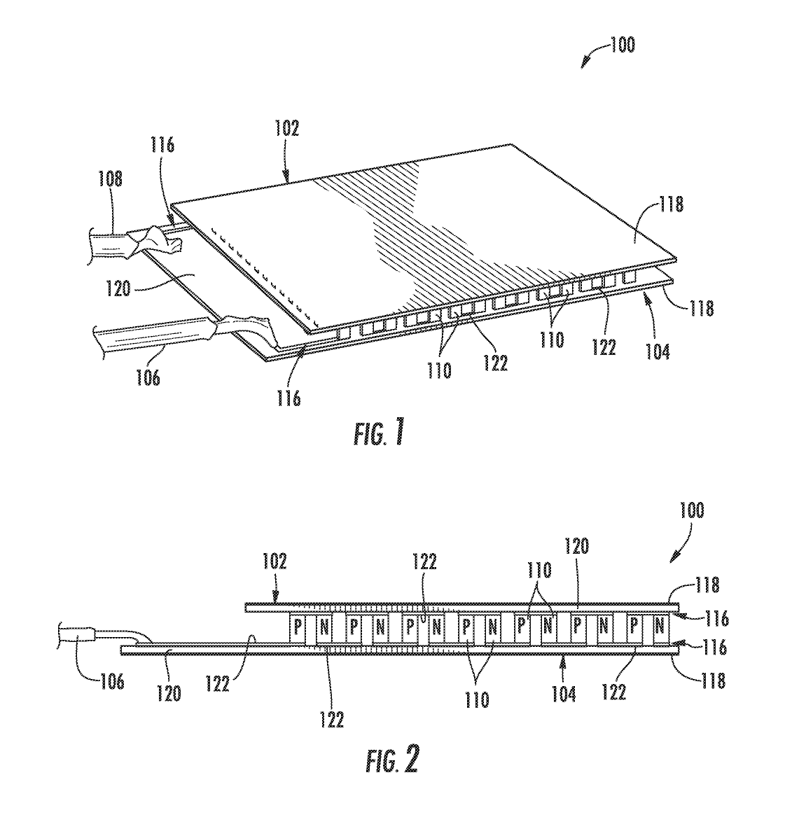

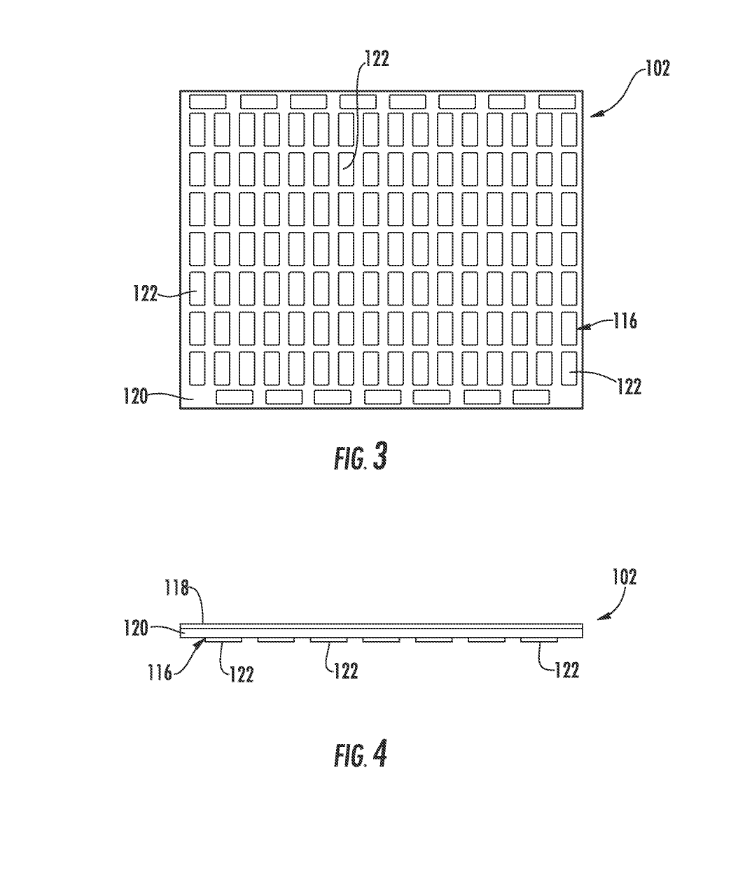

As shown in FIGS. 1 and 2, the illustrated thermoelectric module 100 generally includes a first, upper laminate 102 (broadly, a substrate) and a second, lower laminate 104 (broadly, a substrate) oriented generally parallel to the upper laminate 102 (as viewed in FIGS. 1 and 2). A positive lead wire 106 and a negative lead wire 108 are coupled to the lower laminate 104 for providing power to the thermoelectric module 100 such that the illustrated thermoelectric module 100 generally defines a single circuit. Alternating N-type and P-type thermoelectric elements (each indicated at reference number 110) are disposed generally between the upper and lower laminates 102 and 104. The illustrated N-type and P-type elements 110 are each generally cubic in shape (broadly, cuboid in shape). And, each of the N-type and P-type elements 110 is formed from suitable materials (e.g., bismuth telluride, etc.). In other example embodiments, thermoelectric modules may include configurations of N-type and P-type thermoelectric elements other than alternating configurations (e.g., series configurations, etc.). In addition, thermoelectric elements may have shapes other than cuboid within the scope of the present disclosure.

The upper and lower laminates 102 and 104 of the illustrated thermoelectric module 100 are each generally rectangular in shape. As such, the illustrated thermoelectric module 100 defines a generally rectangular footprint. In addition in the illustrated embodiment, the lower laminate 104 is generally larger than the upper laminate 102 to provide room for coupling the lead wires 106 and 108 to the thermoelectric module 100. In other example embodiments, thermoelectric modules may have substrates with other than rectangular shapes (e.g., circular, oval, square, triangular, etc.) such that they define footprints having other than rectangular shapes and/or may include substrates with different relative sizes than disclosed herein.

In the illustrated embodiment, the upper and lower laminates 102 and 104 each include a layered, laminated, sheet-type construction having a generally rigid structure. In addition, the illustrated upper and lower laminates 102 and 104 are generally prefabricated. For example, the upper and lower laminates 102 may be obtained pre-constructed, and then processed as disclosed herein, for example, for coupling thermoelectric elements 110 therebetween, for use as the thermoelectric module 100, etc. as necessary and/or desired. Example prefabricated laminates suitable for use in the present disclosure include, for example, TLAM™ circuit boards from Laird Technologies (St. Louis, Mo.), etc. It should be appreciated, however, that laminates could be prefabricated to have any structures and/or combinations of structures as necessary for their desired uses within the scope of the present disclosure.

The illustrated upper laminate 102 is substantially the same as the illustrated lower laminate 104. Therefore, the upper laminate 102 will be described next with it understood that a description of the lower laminate 104 is substantially same. It should be appreciated, however, that in other example embodiments thermoelectric modules may include upper laminates having different configurations (e.g., sizes, shapes, constructions, etc.) from lower laminates. For example, thermoelectric modules may include upper laminates that are prefabricated as generally disclosed herein, and lower laminates that include traditional ceramic constructions, etc.

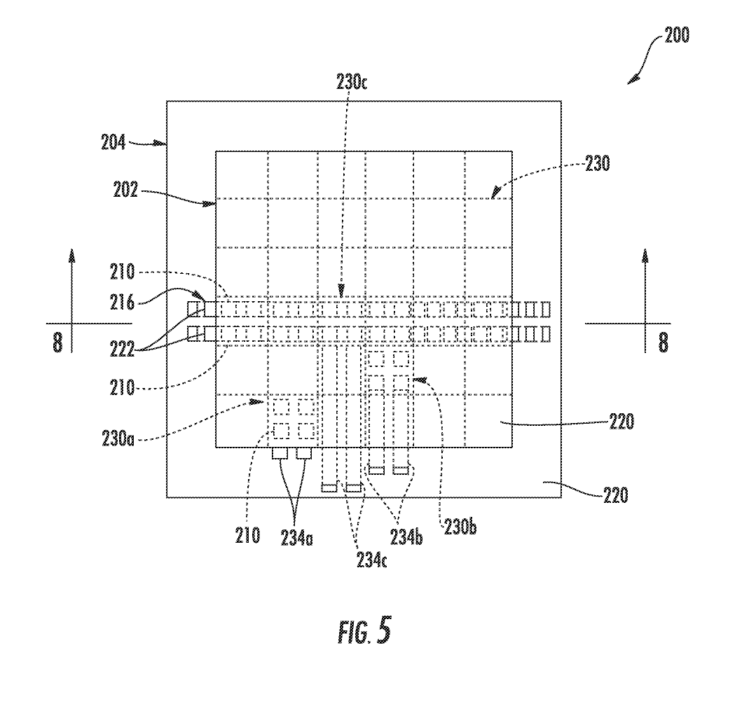

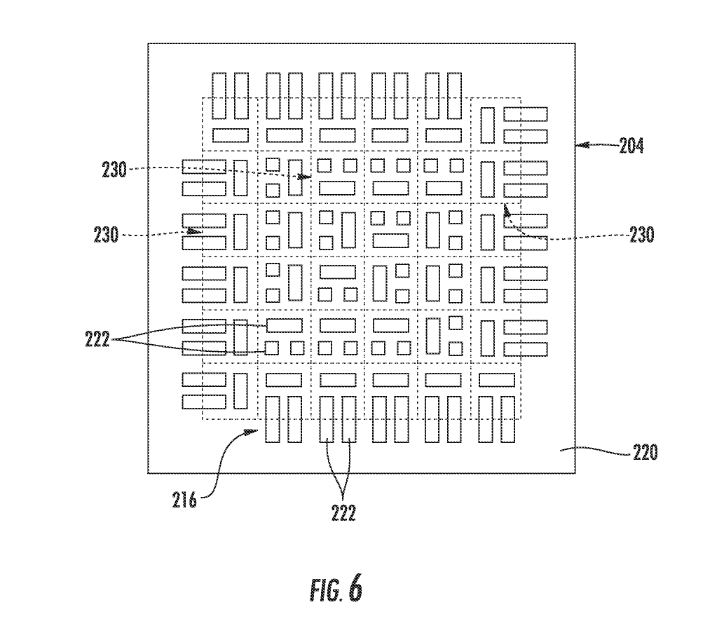

Referring now to FIGS. 3 and 4, the illustrated upper laminate 102 (as generally prefabricated) generally includes a first, inner electrically conductive layer 116 and a second, outer electrically conductive layer 118 (e.g., formed from copper foil, etc.) with a polymeric dielectric layer 120 disposed generally between the inner and outer electrically conductive layers 116 and 118. The inner and outer electrically conductive layers 116 and 118 are coupled to the dielectric layer 120 by suitable processes. For example, the inner and outer electrically conductive layers 116 and 118 may be laminated to, pressed to, etc. the dielectric layer 120.

The inner electrically conductive layer 116 of the illustrated upper laminate 102 is configured to electrically connect the multiple N-type and P-type thermoelectric elements 110 together. For example, at least part of the inner electrically conductive layer 116 of the prefabricated upper laminate 102 is removed (e.g., etched, cut (e.g., milled, water jet cut, eroded, etc.), etc.) from the dielectric layer 120 to define electrically conductive pads 122 (e.g., conducting pads, circuit paths, current paths, etc.) on the prefabricated upper laminate 102 extending across the dielectric layer 120. The electrically conductive pads 122 are configured to electrically couple adjacent N-type and P-type thermoelectric elements 110 together in series for operation of the thermoelectric module 100. The N-type and P-type thermoelectric elements 110 can each be coupled to the electrically conductive pads 122 by suitable operations (e.g., soldering, etc.). The inner electrically conductive layer 116 from which the electrically conductive pads 122 are formed may be constructed from any suitable conducting metallic material such as, for example, copper, nickel, aluminum, stainless steel, combinations thereof, etc. And, any suitable thickness of material may be used for the layer 116 (e.g., six-ounce copper foil, etc.), depending, for example, on desired current capacity, etc.

The outer electrically conductive layer 118 of the illustrated upper laminate 102 (as generally prefabricated) is configured to provide a surface for coupling (e.g., physically coupling such as soldering, thermally coupling, etc.) the thermoelectric module 100 to a desired structure (e.g., within an electrical device, to other thermal components, etc.) and/or to provide stability to the thermoelectric module 100 for handling. The layer 118 may be formed from any suitable conducting metallic material such as, for example, copper, nickel, aluminum, stainless steel, combinations thereof, etc. And, any suitable thickness of material may be used for the layer 118 (e.g., twelve-ounce copper foil, etc.), depending, for example, on desired current capacity, structural stability, use, etc. In some example embodiments of the present disclosure, the outer electrically conductive layer 118 may be substantially removed (e.g., etched, cut (e.g., milled, water jet cut, eroded, etc.), etc.) from the dielectric layer 120 leaving bare dielectric. This can provide, for example, thinner thermoelectric module constructions, etc. And in other example embodiments of the present disclosure, the outer electrically conductive layer 118 may be entirely removed.

The polymeric dielectric layer 120 is configured to electrically insulate circuits included as part of the thermoelectric module 100. The layer 120 may be formed from any suitable electrically insulating material within the scope of the present disclosure. For example, the polymeric dielectric layer 120 may include a cured resin within the scope of the present disclosure (e.g., to provide structural stability to the laminate, rigidity to the laminate, etc.). In this example, the cured resin may be generally brittle, for example, at room temperature, etc. The polymeric dielectric layer 120 may also include one or more additives (e.g., thermally conductive filler particles such as fiberglass, ceramics, etc.) to provide one or more of (or combinations of) enhanced adhesion of the polymeric dielectric layer 120 to the inner and outer electrically conductive layers 116 and 118, enhanced thermal conductivity, enhanced dielectric strength, improved coefficients of thermal expansion, etc. Some example embodiments include one or more polymeric dielectric layers that include thermally conductive filler particles, such as fiberglass, ceramics, etc. to provide one or more thermally enhanced polymeric dielectric layers. In some example embodiments, polymeric dielectric layers may be cured ceramic-filled dielectric layers that are not flexible at room temperature, but instead are brittle at room temperature and will crack when bent. In various example embodiments, dielectric layers may include thickness dimensions of at least about 0.002 inches (at least about 0.05 millimeters). For example, in one embodiment a dielectric layer includes a thickness dimension of about 0.003 inches (about 0.075 millimeters). And, in another example embodiment, a dielectric layer includes a thickness dimension of about 0.004 inches (about 0.1 millimeters). Dielectric layers may have any other desired thickness within the scope of the present disclosure (e.g., based on voltage requirements, etc.).

In an example operation of the illustrated thermoelectric module 100, the thermoelectric module 100 is electrically connected to one or more direct current (DC) power sources (e.g., three, six, twelve volt power sources, other power sources, etc.) (not shown) via the positive and negative lead wires 106 and 108 and is operated as a thermoelectric cooler. Electrical current passing through the thermoelectric module 100 causes heat to be pumped from one side (e.g., the lower laminate 104, etc.) of the thermoelectric module 100 to the other side (e.g., the upper laminate 102, etc.) of the thermoelectric module 100. Naturally, this creates a warmer side (e.g., the upper laminate 102, etc.) and a cooler side (e.g., the lower laminate 104, etc.) for the thermoelectric module 100 such that objects exposed to the cooler side may subsequently be cooled (e.g., such that heat can be transferred from the object to the cooler side to the warmer side, etc.). While example operation of the illustrated thermoelectric module 100 has been described in connection with a thermoelectric cooler, it should be understood that the illustrated thermoelectric module 100 could also be operated as a thermoelectric generator within the scope of the present disclosure.

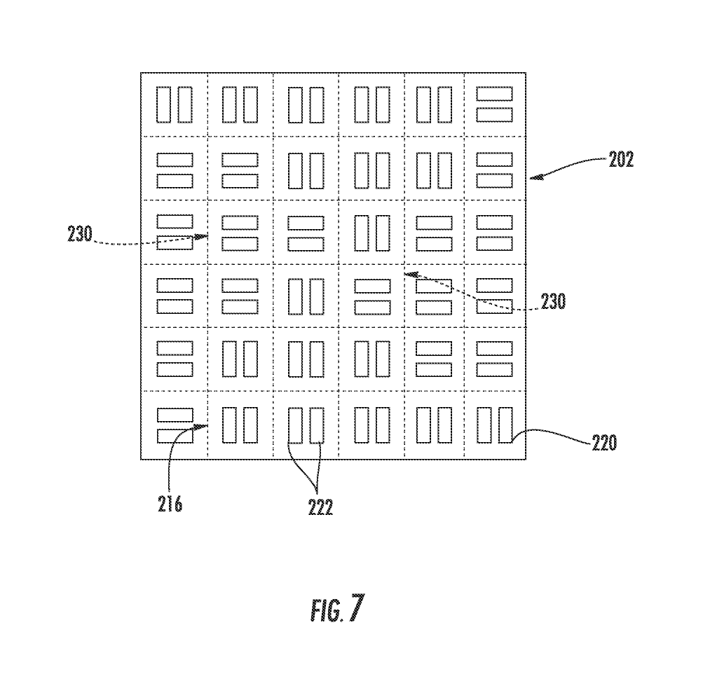

FIGS. 5-9 illustrate another example embodiment of a thermoelectric module 200 of the present disclosure. The thermoelectric module 200 of this embodiment is similar to the thermoelectric module 100 previously described and illustrated in FIGS. 1-4. In this embodiment, however, thermoelectric elements 210 are arranged to define multiple subcircuits 230 within the thermoelectric module 200 which allows cooling power to be raised and lowered in different areas separately, and dynamically. To accommodate the multiple subcircuits 230, a lower laminate 204 of the thermoelectric module 200 includes a multilayer circuit assembly for use in connecting lead wires (not shown) to each of the multiple subcircuits 230.

As shown in FIG. 5, the thermoelectric module 200 of this embodiment generally includes an upper laminate 202, the lower laminate 204, and an array of thermoelectric elements 210 (e.g., P-type and N-type thermoelectric elements, etc.) disposed generally between the upper and lower laminates 202 and 204. The thermoelectric elements 210 are arranged in multiple two by two arrays. These arrays define thirty-six electrically independent subcircuits 230 of the thermoelectric module 200. Thus, the illustrated thermoelectric module 200 is essentially a six by six square array of thermoelectric sub-modules (or subcircuits 230), with each sub-module having a two by two square array of thermoelectric elements 210. The six by six square arrays of sub-modules (or subcircuits 230) as well as the two by two arrays of thermoelectric elements 210 are illustrated with broken lines in the drawings. However, only a few example two by two arrays thermoelectric elements 210 are shown as part of subcircuits 230 in FIG. 5. With this said, it should be appreciated that all of the illustrated subcircuits 230 each include a two by two array of thermoelectric elements 210 (even though not illustrated).

The subcircuits 230 can be connected together electrically in series, or in parallel, or in an arbitrary series-parallel combination to thereby cause a desired amount of current to pass through them even if only a single fixed DC power source is provided. Thus, the same current may be passing through all of the subcircuits 230, but it can be adjusted in real time to pump a changing amount of heat with optimum efficiency. This may provide advantages in both cooling and power generation.

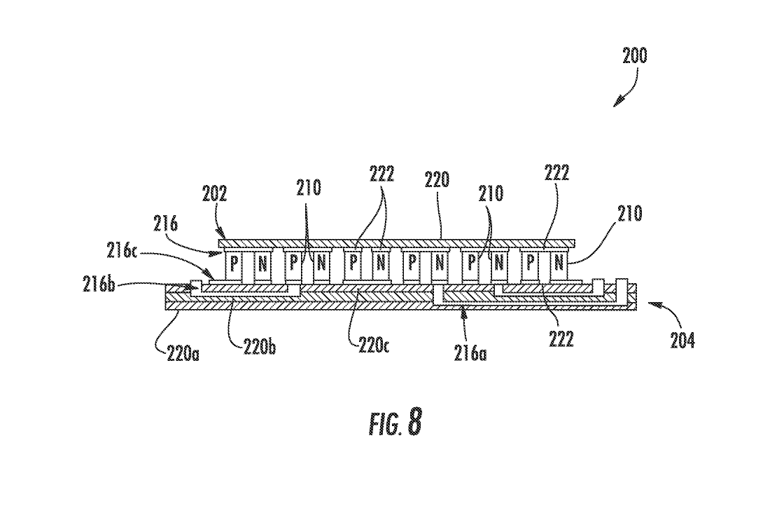

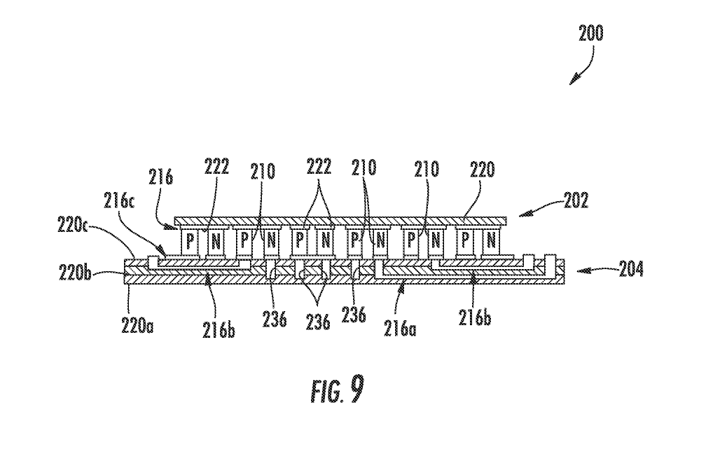

As shown in FIGS. 6 and 7, the lower laminate 204 generally includes (among other layers) an inner electrically conductive layer 216 coupled to a dielectric layer 220. The inner electrically conductive layer 216 is etched to create multiple electrically conductive pads 222 for interconnecting the thermoelectric elements 210 within each subcircuit 230. Similarly, the upper laminate 202 generally includes an inner electrically conductive layer 216 coupled to a dielectric layer 220. The inner electrically conductive layer 216 is etched to create multiple electrically conductive pads 222 for interconnecting the thermoelectric elements 210 within each subcircuit 230. The upper laminate 202 may be a single piece of material, or may be physically divided into thirty-six squares consistent with the six by six array of sub-modules.

Referring again to FIG. 5, each of the electrically independent subcircuits 230 (e.g., outermost subcircuits 230a and interior subcircuits 230b and 230c, etc.) includes a pair of current paths 234 leading out of the thermoelectric module 200 (e.g., current paths 234a-c leading out of subcircuits 230a-c, etc.). The twenty subcircuits 230 located around the periphery of the thermoelectric module 200 are directly accessible along the edge portions of the thermoelectric module 200 via the current paths 234a (which are generally defined by an upper electrically conductive layer 216a of the lower laminate 204 and thus also include electrically conductive pads 222 (see, e.g., FIGS. 8 and 9, etc.)—this layer is generally indicated at reference number 216 in FIG. 5). However, these current paths 234a generally fill the available space along the edge portions of the thermoelectric module 200. Thus, the current paths 234b and 234c for the interior subcircuits 230b and 230c must be layered within the lower laminate 204 (e.g., buried below the current paths 234a for the outermost subcircuits 230a (see, e.g., FIGS. 8 and 9, etc.), etc.). For example, in FIG. 5 (and FIGS. 8 and 9), current paths 234b for subcircuit 230b are located generally in a middle layer of the lower laminate 204, and current paths 234c for subcircuit 230c are located generally in a lower layer of the lower laminate 204. This will be described in more detail next.

With reference now to FIG. 8, and as previously described, the lower laminate 204 of the illustrated thermoelectric module 200 includes a generally layered construction having six layers. This generally includes lower, middle, and upper conductive layers 216a-c (or circuit layers, or current paths, etc.) and lower, middle, and upper dielectric layers 220a-c. The dielectric layers 220a-c are provided generally between the conductive layers 216a-c, for example, for insulating the thermoelectric module 200 from the environment, for insulating different conductive layers 216a-c, etc. The conductive layers 216a-c are provided for making electrical connections with the thermoelectric elements 210. Current paths 234 (e.g., current paths 234a-c in FIG. 5, etc.) are generally defined by (and are generally included as part of) the respective conductive layers 216a-c in FIG. 8 and are made, for example, by successive operations of coupling conductive layer 216a to dielectric layer 220a, etching the conductive layer 216a to produce current path 234a (FIG. 5), coupling dielectric layer 220b to the remaining portion of conductive layer 216a (e.g., current patch 234a, etc.) (as illustrated in FIG. 8, the dielectric layer 220b may fill in the areas where conductive layer 216a is etched away), coupling conductive layer 216b to dielectric layer 220b, etching the conductive layer 216b to produce current path 234b (FIG. 5), coupling dielectric layer 220c to the remaining portion conductive layer 216b (e.g., current patch 234b, etc.) (as illustrated in FIG. 8, the dielectric layer 220c may fill in the areas where conductive layer 216b is etched away), coupling conductive layer 216c to dielectric layer 220c, and etching the conductive layer 216c to produce current path 234c (FIG. 5) (which also define electrically conductive pads 222).

It should be appreciated that there are some areas in the lower laminate 204 with three layers of dielectric material but no buried current paths (or buried conductive layers), for example, below the thermoelectric elements 210 toward a center of the thermoelectric module 200. Buried current paths are only required in certain areas in the thermoelectric module 200, and are etched away from the dielectric layers 220a-c where not needed. However, thermal conductivity of the dielectric layers 220a-c is not as good as that of the conductive layers 216a-c. Therefore, as shown in FIG. 9, thermal vias 236 may be added to the lower laminate 204 to help improve heat transfer through the lower laminate 204. The thermal vias 236 are formed by making holes through the upper and middle dielectric layers 220c and 220b, and filling the holes with metal (e.g., through a chemical deposition process, etc.). The thermal vias 236 may extend up to the lower dielectric layer 220a, or the vias may extend partially into (but not through) the lower dielectric layer 220a. The lower dielectric layer 220a is left substantially intact in order to electrically isolate the thermal vias 236 from the surrounding environment as the metal in the thermal vias 236 would conduct electricity as well as heat. Alternatively, the upper dielectric layer 220c could be left intact to isolate the thermal vias, and the thermal vias could be formed through the middle and lower dielectric layers 220b and 220a. The thermal vias 236 are positioned, sized, and shaped as appropriate to transport heat between the surrounding environment and one end of a thermoelectric element 210.

In this example embodiment, the layered construction of the lower laminate 204 may also allow for including sensors or other components therein as desired. In addition, the lower laminate 204 may include attachment points for controllers (e.g., chip socket, etc.) and/or edge connectors for external controllers.

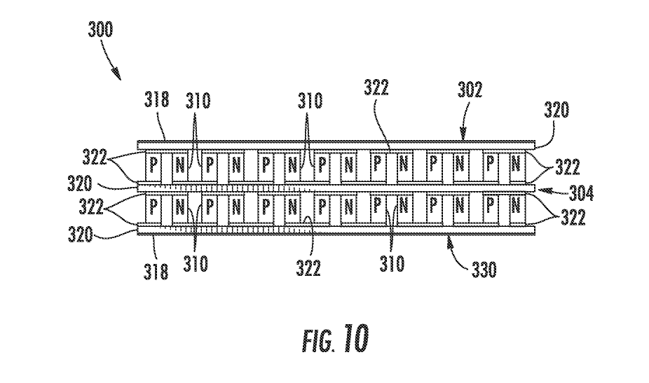

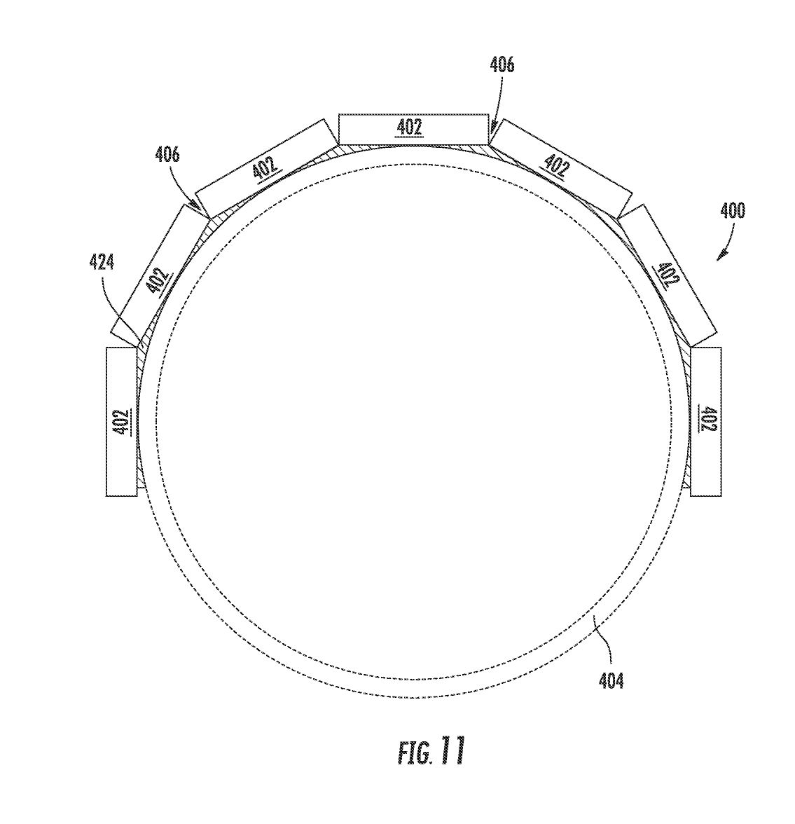

FIG. 10 illustrates another example embodiment of a thermoelectric module 300 of the present disclosure. In this example embodiment, the thermoelectric module 300 is a multistage thermoelectric module with multiple cascading laminates (e.g., 302, 304, and 330, etc.) For example, the illustrated multistage thermoelectric module 300 generally includes a first laminate 302, a second laminate 304, and a third laminate 330. Multiple thermoelectric elements 310 are disposed between the first and second laminates 302 and 304 and between the second and third laminates 304 and 330 (such that the second laminate 304 is disposed generally between the first and third laminates 302 and 330). The first laminate 302 generally includes a dielectric layer 320 and a layer 322 of electrically conductive material. The second laminate 304 generally includes a dielectric layer 320, and two layers 322 of electrically conductive material. And, the third laminate 330 generally includes a dielectric layer 320 and a layer 322 of electrically conductive material. The dielectric layer 320 of at least one of the first, second, and third laminates 302, 304, and 330 is a polymeric dielectric layer. The layers 322 of electrically conductive material of the first, second, and third laminates 302, 304, and 330 are each etched to form electrically conductive pads (also indicated at reference numeral 322) for electrically coupling the thermoelectric elements 310 together between the first and second laminates 302 and 304 and between the second and third laminates 304 and 330. In the illustrated thermoelectric module 300, the first and third laminates 302 and 330 also include outer electrically conductive layers 318. In other example embodiments, multistage thermoelectric modules may include more than three laminates with multiple thermoelectric elements disposed between each of the laminates within the scope of the present disclosure.

In another example embodiment of the present disclosure, a thermoelectric module generally includes an upper laminate, a lower laminate, and multiple thermoelectric elements disposed therebetween. The upper laminate generally includes a polymeric dielectric layer and inner and outer layers of copper (or other suitable material). And, the lower laminate generally includes a traditional ceramic dielectric layer and an inner layer of electrically conductive pads. The inner layer of copper of the upper laminate is etched to form electrically conductive pads on the first laminate. The thermoelectric elements are coupled to the electrically conductive pads of the upper laminate and the electrically conductive pads of the lower laminate for electrically coupling the thermoelectric elements together.

In another example embodiment of the present disclosure, a thermoelectric module generally includes a prefabricated upper laminate, a prefabricated lower laminate, and multiple thermoelectric elements disposed therebetween. The prefabricated upper laminate generally includes a polymeric dielectric layer and inner and outer layers of copper. And, the prefabricated lower laminate generally includes a polymeric dielectric layer, an inner layer of copper, and an outer layer of aluminum. The inner layers of copper of each of the upper and lower prefabricated laminates are etched to form electrically conductive pads on the first and second prefabricated laminates from the inner copper layers remaining on the first and second prefabricated laminates for electrically coupling the thermoelectric elements together. And, the outer aluminum layer of the lower prefabricated laminate is shaped with grooves (e.g., corrugated, etc.) to provide structure for receiving thermal interface materials when coupling the thermoelectric module to additional components and/or additional structural rigidity to the laminate. The inner layer of copper of the upper prefabricated laminate and/or the inner layer of copper of the lower prefabricated laminate may have a thickness dimension ranging from about 0.001 inches (about 0.035 millimeters) to about 0.008 inches (about 0.203 millimeters). And, the outer aluminum layer of the lower prefabricated laminate may have a thickness dimension ranging from about 0.04 inches (about 1.02 millimeters) to about 0.062 inches (about 1.575 millimeters).

In still another example embodiment of the present disclosure, a thermoelectric module generally includes an upper laminate, a lower laminate, and multiple thermoelectric elements disposed therebetween. Each of the upper and lower laminates generally include a polymeric dielectric layer and an inner layer of copper. The inner layers of copper of each of the upper and lower laminates are etched to form electrically conductive pads for electrically coupling the thermoelectric elements together. A release liner is coupled by suitable operations to an outer surface of the upper and/or lower laminate (e.g., to an outer surface of the dielectric layer of the upper and/or lower laminate in place of or instead of a metallic layer, etc.). The release liner can then be removed by an ultimate consumer of the thermoelectric module to provide a module with bare dielectric on the outside for subsequent use (without having to etch off an entire layer of metallic material).

In another example embodiment of the present disclosure, a thermoelectric module generally includes a prefabricated upper laminate, a prefabricated lower laminate, and multiple thermoelectric elements disposed therebetween. The upper laminate generally includes a polymeric dielectric layer and inner and outer layers of copper (or other suitable material). And, the lower laminate generally includes a polymeric dielectric layer and inner and outer layers of copper (or other suitable material). The inner layers of copper of each of the upper and lower laminates are etched to form electrically conductive pads for electrically coupling the thermoelectric elements together between the upper and lower laminates. And, the outer layer of copper of the upper laminate and/or the outer layer of copper of the lower laminate may be etched to form electrically conductive pads configured for electrically coupling (e.g., soldering, etc.) the thermoelectric module to an external component. Thus, the outer copper layer of the upper and/or lower laminate (as etched) could provide thermally conductive but separate, isolated circuits for carrying current between the external component and the thermoelectric module.

In another example embodiment of the present disclosure, a thermoelectric module generally includes a prefabricated upper laminate, a prefabricated lower laminate, and multiple thermoelectric elements disposed therebetween. The prefabricated upper laminate generally includes a polymeric dielectric layer and an inner layer of copper (or other suitable material). And, the prefabricated lower laminate generally includes a polymeric dielectric layer and an inner layer of copper (or other suitable material). The inner layers of copper of each of the prefabricated upper and lower laminates are etched to form electrically conductive pads on the prefabricated laminates from the inner copper layers remaining on the prefabricated laminates for electrically coupling the thermoelectric elements together between the prefabricated upper and lower laminates. The outer layers of at least one of the prefabricated upper and lower laminates may be bare leaving exposed dielectric material (such that the laminate is prefabricated, or premade, to have a generally bare outer layer leaving at least part of the dielectric material exposed).

In a further example embodiment of the present disclosure, a method of making a thermoelectric module generally includes coupling (e.g., soldering, etc.) multiple thermoelectric elements to upper and lower prefabricated laminates such that the multiple thermoelectric elements are disposed generally between the upper and lower prefabricated laminates. The upper and lower prefabricated laminates each generally include a first, inner electrically conductive layer (e.g., copper, nickel, combinations thereof, etc.) and a second, outer electrically conductive layer (e.g., copper, aluminum, combinations thereof, etc.) coupled to a polymeric dielectric layer. At least part of the inner electrically conductive layers are removed to form electrically conductive pads to which the multiple thermoelectric elements are coupled. The example method may further include substantially removing the outer electrically conductive layer from the upper and/or lower prefabricated laminates.

Thermoelectric modules of the present disclosure may form the basis for thermoelectric assemblies. As will be described further hereinafter, a plurality of thermoelectric modules may be electrically and/or mechanically connected to create a thermoelectric assembly. An assembly may be useful when an area to be heated/cooled or used for power generation is larger than can be accomplished with a single thermoelectric module or would otherwise benefit from more than one thermoelectric module. Additionally, articulated assemblies, as disclosed herein, may be particularly useful in connection with surfaces that are non-planar (e.g., curved, cylindrical, round, triangular, hexagonal, etc.)

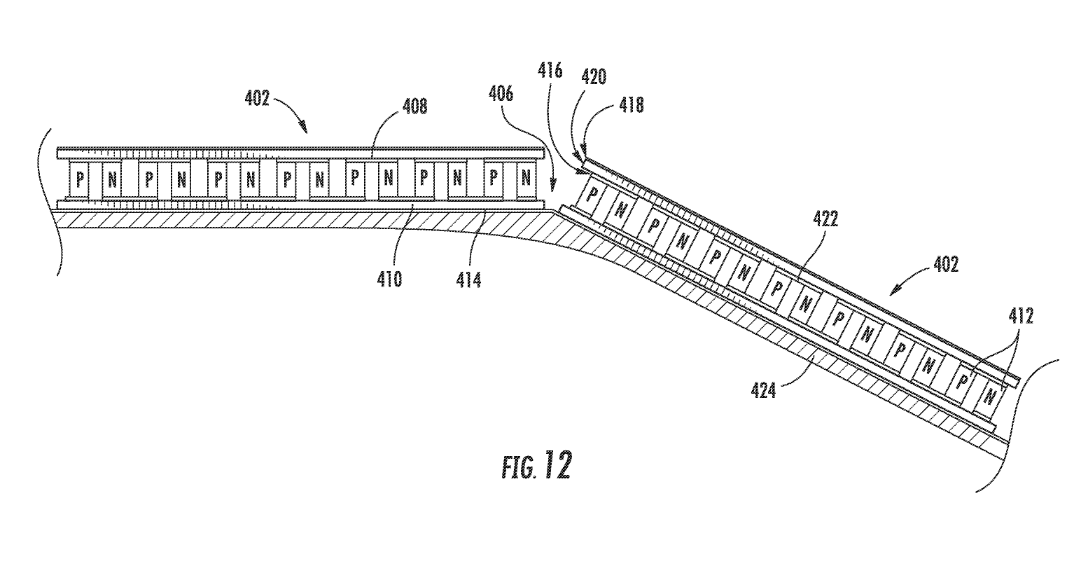

FIGS. 11-13 illustrate an example embodiment of a thermoelectric assembly 400 including one or more aspects of the present disclosure. The illustrated thermoelectric assembly 400 can be used, for example, as a heat pump, an electrical power generator, etc.

As shown in FIG. 11, the assembly 400 includes a plurality of thermoelectric modules 402. The assembly 400 may be circumferentially wrapped generally about an outer surface of a pipe 404 (or other fluid conduit). After being wrapped about the pipe 404, the assembly 400 may then be used for extracting power from or cooling/dissipating heat from the pipe 404 and fluid within the pipe 404. Alternatively, the assembly 400 may also be used with different fluid conduits besides the pipe 404, such as pipes in different sizes and shapes. For example, the assembly 400 may also be used with pipes having non-circular cross-sections (e.g., rectangular cross-sections, triangular cross-sections, ovular sections, etc.).

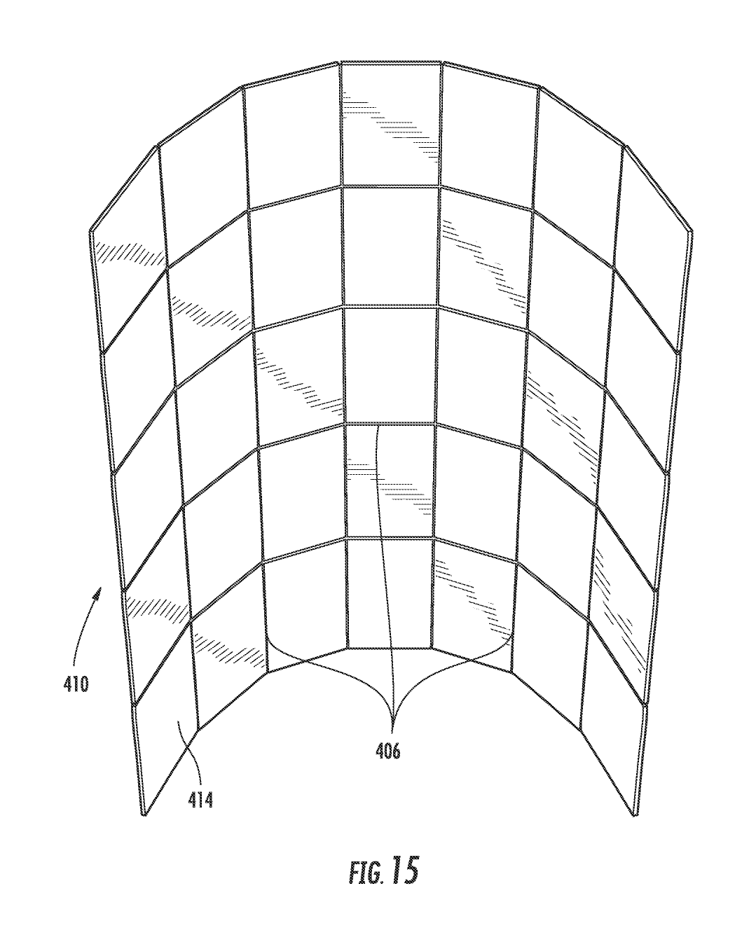

In FIG. 11, the assembly 400 appears as a single row of thermoelectric modules 402. The assembly 400 may be such a single row of thermoelectric modules 402. However, (as seen in, for example, FIGS. 14 and 15) the assembly 400 may include multiple rows of thermoelectric modules 402.

The thermoelectric modules 402 (as will be discussed more fully below) are substantially rigid (e.g., they are not highly flexible and/or cannot easily be flexed without potentially damaging the module 402). To permit the assembly 400 to be used with items (such as pipe 404) not having simply a planar shape, the assembly 400 is an articulated assembly. Accordingly, the assembly 400 includes a plurality of articulation points (also called hinges) 406 between adjacent thermoelectric modules 402 in the assembly 400. In some embodiments, the hinges 406 are living hinges that may be plastically deformable portions of a common layer of the thermoelectric modules 402 (as will be discussed below).

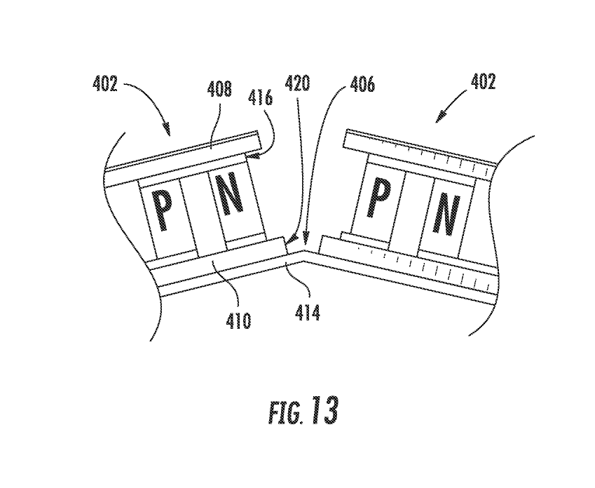

The thermoelectric modules 402 in the assembly 400 may be any suitable thermoelectric module, such as, for example, thermoelectric modules 100, 200, 300 disclosed herein. FIG. 12 illustrates two example thermoelectric modules 402 of the assembly 400 substantially the same as thermoelectric modules 100 described above.

The thermoelectric modules 402 may include (as best seen in FIG. 12) a substantially rigid upper laminate (or substrate) 408 and a substantially rigid lower laminate (or substrate) 410. A plurality of thermoelectric elements 412 is disposed generally between the upper laminate 408 and the lower laminate 410. The assembly 400 includes a thermally conductive layer 414. The thermally conductive layer 414 is mechanically connected to each of the thermoelectric modules 402.

The illustrated upper laminate 408 (as generally prefabricated) generally includes a first, inner electrically conductive layer 416 and a second, outer electrically conductive layer 418 (e.g., formed from copper foil, aluminum, etc.) with a polymeric dielectric layer 420 disposed generally between the inner and outer electrically conductive layers 416 and 418. The inner and outer electrically conductive layers 416 and 418 are coupled to the dielectric layer 420 by suitable processes. For example, the inner and outer electrically conductive layers 416 and 418 may be laminated to, pressed to, etc. the dielectric layer 420.

The inner electrically conductive layer 416 of the illustrated upper laminate 408 is configured to electrically connect the multiple N-type and P-type thermoelectric elements 412 together. For example, at least part of the inner electrically conductive layer 416 of the prefabricated upper laminate 408 is removed (e.g., etched, cut (e.g., milled, water jet cut, eroded, etc.), etc.) from the dielectric layer 420 to define electrically conductive pads 422 (e.g., conducting pads, circuit paths, current paths, etc.) on the prefabricated upper laminate 408 extending across the dielectric layer 420. The electrically conductive pads 422 are configured to electrically couple adjacent N-type and P-type thermoelectric elements 412 together in series for operation of the thermoelectric modules 402. The N-type and P-type thermoelectric elements 412 can each be coupled to the electrically conductive pads 422 by suitable operations (e.g., soldering, etc.). The inner electrically conductive layer 416 from which the electrically conductive pads 422 are formed may be constructed from any suitable conducting metallic material such as, for example, copper, nickel, aluminum, stainless steel, combinations thereof, etc. And, any suitable thickness of material may be used for the layer 416 (e.g., six-ounce copper foil, etc.), depending, for example, on desired current capacity, etc.

The outer electrically conductive layer 418 of the illustrated upper laminate 408 (as generally prefabricated) is configured to provide a surface for coupling (e.g., physically coupling such as soldering, thermally coupling, spring clips, etc.) the thermoelectric module 402 to a desired structure (e.g., within an electrical device, to other thermal components, to a heat sink, to a cooling fan, etc.) and/or to provide stability to the thermoelectric module 402 for handling. By way of example only, one or more heat sinks may be attached to the thermoelectric module 402 of the thermoelectric assembly 400, such as by using spring clips or other mechanical attachment at two edges of a thermoelectric module 402. As another example, threads may be tapped directly into a circuit board. A thermal interface material (e.g., thermal grease, etc.) may be used between a heat sink and thermoelectric module. In embodiments in which heat sinks are supplied, there may also be provided a fan and a self-adhesive (or otherwise mountable) plastic film to guide airflow from the fan across the heat sinks.

The layer 418 may be formed from any suitable conducting metallic material such as, for example, copper, nickel, aluminum, stainless steel, combinations thereof, etc. And, any suitable thickness of material may be used for the layer 418 (e.g., twelve-ounce copper foil, etc.), depending, for example, on desired current capacity, structural stability, use, etc. In some example embodiments of the present disclosure, the outer electrically conductive layer 418 may be substantially removed (e.g., etched, cut (e.g., milled, water jet cut, eroded, etc.), etc.) from the dielectric layer 420 leaving bare dielectric. This can provide, for example, thinner thermoelectric assembly constructions, etc. And in other example embodiments of the present disclosure, the outer electrically conductive layer 418 may be entirely removed.

The polymeric dielectric layer 420 is configured to electrically insulate circuits included as part of the thermoelectric module 402. The layer 420 may be formed from any suitable electrically insulating material within the scope of the present disclosure. For example, the polymeric dielectric layer 420 may include a cured resin within the scope of the present disclosure (e.g., to provide structural stability to the laminate, rigidity to the laminate, etc.). In this example, the cured resin may be generally brittle, for example, at room temperature, etc. The polymeric dielectric layer 420 may also include one or more additives (e.g., thermally conductive filler particles such as fiberglass, ceramics, etc.) to provide one or more of (or combinations of) enhanced adhesion of the polymeric dielectric layer 420 to the inner and outer electrically conductive layers 416 and 418, enhanced thermal conductivity, enhanced dielectric strength, improved coefficients of thermal expansion, etc. Some example embodiments include one or more polymeric dielectric layers that include thermally conductive filler particles, such as fiberglass, ceramics, etc. to provide one or more thermally enhanced polymeric dielectric layers. In some example embodiments, polymeric dielectric layers may be cured ceramic-filled dielectric layers that are not flexible at room temperature, but instead are brittle at room temperature and will crack when bent. In various example embodiments, dielectric layers may include thickness dimensions of at least about 0.002 inches (at least about 0.05 millimeters). For example, in one embodiment a dielectric layer includes a thickness dimension of about 0.003 inches (about 0.075 millimeters). And, in another example embodiment, a dielectric layer includes a thickness dimension of about 0.004 inches (about 0.1 millimeters). Dielectric layers may have any other desired thickness within the scope of the present disclosure (e.g., based on voltage requirements, etc.).

The illustrated lower laminate 410 (as generally prefabricated) also generally includes a first, inner electrically conductive layer 416 with a polymeric dielectric layer 420. The inner electrically conductive layer 416 is coupled to the dielectric layer 420 by suitable processes. For example, the inner electrically conductive layers 416 may be laminated to, pressed to, etc. the dielectric layer 420.

The thermally conductive layer 414 may be generally the same as the outer electrically conductive layer 418 discussed above. However, unlike the embodiment of the thermoelectric module 100, in which each module includes a separate outer electrically conductive layer 118, in the assembly 400, a plurality of thermoelectric modules 402 share a common thermally conductive layer 414. The thermally conductive layer 414 may be a substantially contiguous and substantially rigid layer. The thermally conductive layer 414 may also be electrically conductive. For example, the thermally conductive layer 414 may be a metal material, such as copper, nickel, aluminum, stainless steel, combinations thereof, etc. And, any suitable thickness of material may be used (e.g., twelve-ounce copper foil, etc.), depending, for example, on desired current capacity, structural stability, use, etc.

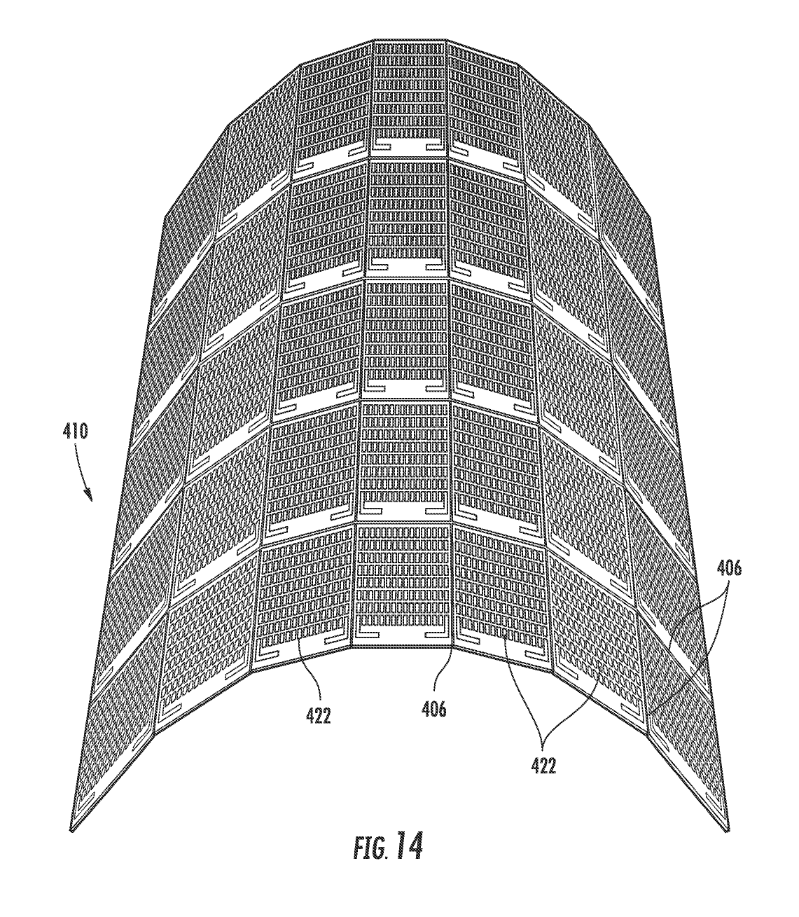

The hinges 406 of the assembly 400 are created in the lower laminate 410 and/or the thermally conductive layer 414 (which may collectively be considered a lower substrate of the assembly 400). As best seen in FIGS. 12 and 13, the lower laminate 410 is removed in the area of the hinge 406, but the thermally conductive layer 414 remains. This increases flexibility and/or permits the assembly 400 (or more specifically, the thermally conductive layer 414) to be flexed or bent (e.g., plastically deformed, etc.) in the area of the hinge 406, thus creating articulation points for the assembly 400.

The thermally conductive layer 414 may also be scored in the area of the hinge 406. Scoring increases flexibility and/or creates an area in which the thermally conductive layer 414 is more likely to deform (e.g., plastically deform, etc.) when a user attempts to bend the assembly 400. This results in simplified shaping (e.g., bending, plastically deforming, etc.) of the assembly 400 and generally produces consistent, repeatable articulation points (e.g., hinges). The scoring of the thermally conductive layer 414 may be accomplished by any suitable method, for example by cutting, etching, removing material, etc. The scoring may be performed on the inside of the thermally conductive layer 414 (e.g., the side adjacent the dielectric layer 420) and/or the outer side of the thermally conductive layer 414 (e.g., the side opposite the dielectric layer 420).

As shown in the illustrated embodiment of FIG. 12, the assembly 400 includes a thermal interface layer 424 mechanically (and thermally) coupled to the thermally conductive layer 414. The thermal interface layer 424 is preferably relatively soft, conformable, and compliable, such that the thermal interface material 424 is able to conform and make good intimate thermal contact with non-planar surfaces (such as the outer circumferential surface of the pipe 404). This intimate contact helps form a better heat path from the non-planar surface to the thermoelectric modules 402 via the thermal interface material 424, as compared to a heat path formed (without using any thermal interface material 424) directly from the a non-planar surface (such as pipe 404). As can be seen in FIG. 11, because of the rigidity of the thermoelectric modules 402 (and the articulated, as opposed to flexible, nature of the assembly 400), the thermally conductive layer 414 (and hence, the modules 402) may only be capable of direct contact with the outer surface of the pipe 404 at a limited number of points or areas. Essentially, each thermoelectric module 402 is tangent to the surface of the pipe 404 and intersects the outer surface of the pipe 404 at only one point or area. But the thermal interface material 424 is able to conform to the shape of the pipe 404 (or other surface) to fill the gaps in contact between the assembly 400 and the pipe 404 (or other surface to which it is attached). As shown in FIG. 11, the thickness of the thermal interface material 424 (e.g., thermal gap filler, etc.) may be determined such that when the assembly 400 is flexed or bent around the pipe 404, the thermal interface material 424 comes into contact with the entire circumferential area of the pipe 404, but is relatively thin in the center of each thermoelectric module 402. Depending on the particular embodiment and/or end-customer for a thermoelectric assembly, the assembly may be supplied with gap fillers (or other thermal interface material) of different thicknesses to accommodate different pipe diameters. The gap filler may be covered with a protective liner (e.g., thin plastic sheet, etc.) until installation, and the gap filler may be configured so as to adhere to the thermoelectric assembly by its own tackiness. Alternatively, other embodiments may not include any thermal interface material 424.

The thermal interface material 424 may be formed from a wide range of materials, which preferably are compliant or conformable materials having generally low thermal resistance and generally high thermal conductivity. Exemplary materials that may be used for the thermal interface material 424 include compliant or conformable silicone pads, silk screened materials, polyurethane foams or gels, thermal putties, thermal greases, thermally-conductive additives, gap filler materials, phase change materials, combinations thereof, etc. In some of these embodiments, the compliant or conformable materials comprise a resiliently compressible material for compressively contacting and conforming to surfaces to which they contact (e.g., the pipe's outer surface). For example, a compliant or conformable thermal interface material pad may be used having sufficient compressibility and flexibility for allowing the pad to relatively closely conform to the size and outer shape of the outer surface of pipe 404. Different material may be used for different end uses of the assembly 400. For example, is the assembly 400 is to be used with a smaller diameter pipe, there will be larger gaps between the surface of the pipe and the assembly 400. Accordingly a thermal interface material 424 that is thicker, is more compressible, has better thermal transfer characteristics, etc. may be desirable. Some embodiments include a thermal interface material pad having an adhesive backing (e.g., a thermally-conductive and/or electrically-conductive adhesive, etc.) for helping attach the assembly 400 to the pipe 404. Also, for example, a compliant or conformable thermal phase change material may be used in some embodiments. In such embodiments, the thermal phase change material may be a generally solid pad at room temperature that melts at increased temperatures to conform and make intimate contact with a surface (such as the pipe 404). In other embodiments, the compliant or conformable materials may comprise form-in-place materials dispensed onto the assembly 400 using form-in-place dispensing equipment, a hand-held dispenser, or a silk screening process, or a combination thereof, etc.

Table 1 below lists some exemplary thermal interface materials that may be used in one or more embodiments disclosed herein. These exemplary materials are commercially available from Laird Technologies, Inc. of Saint Louis, Mo., and, accordingly, have been identified by reference to trademarks of Laird Technologies, Inc. This table is provided for purposes of illustration only and not for purposes of limitation.

TABLE 1

| | | | | | Pressure of |
|---|---|---|---|---|---|
| | | | | | Thermal |
| | | | Thermal | Thermal | Impedance |
| | Construction | | Conductivity | Impedance | Measurement |
| Name | Composition | Type | [W/mK] | [° C.-cm²/W] | [kPa] |
| T-flex ™ 320 | Ceramic filled | Gap | 1.2 | 8.42 | 69 |
| | silicone | Filler | | | |
| | elastomer | | | | |
| T-flex ™ 520 | Ceramic filled | Gap | 2.8 | 2.56 | 69 |
| | silicone | Filler | | | |
| | elastomer | | | | |
| T-flex ™ 620 | Reinforced | Gap | 3.0 | 2.97 | 69 |
| | boron nitride | Filler | | | |
| | filled silicone | | | | |
| | elastomer | | | | |
| T-flex ™ 640 | Boron nitride | Gap | 3.0 | 4.0 | 69 |
| | filled silicone | Filler | | | |
| | elastomer | | | | |
| T-flex ™ 660 | Boron nitride | Gap | 3.0 | 8.80 | 69 |
| | filled silicone | Filler | | | |
| | elastomer | | | | |
| T-flex ™ 680 | Boron nitride | Gap | 3.0 | 7.04 | 69 |
| | filled silicone | Filler | | | |
| | elastomer | | | | |
| T-flex ™ 6100 | Boron nitride | Gap | 3.0 | 7.94 | 69 |
| | filled silicone | Filler | | | |
| | elastomer | | | | |
| T-pli ™ 210 | Boron nitride | Gap | 6 | 1.03 | 138 |
| | filled, silicone | Filler | | | |
| | elastomer, | | | | |
| | fiberglass | | | | |
| | reinforced | | | | |
| T-grease ™ 880 | Silicone-based | Thermal | 3.1 | 0.058 | 345 |
| | grease | Grease | | | |
| Tpcm ™ 905C | Ceramic-filled | Phase | 0.7 | 0.19 | 345 |
| | Phase Change | Change | | | |
| | Material | Material | | | |

FIGS. 14 and 15 illustrate one example embodiment of a lower laminate 410 for a thermoelectric assembly 400. As can be seen, the illustrated lower laminate 410 includes conductive pads 422 for thirty-five (35) thermoelectric modules 402 arranged in five rows of seven thermoelectric modules 402. Hinges 406 are located between adjacent thermoelectric modules 402. In the illustrated lower laminate 410, there are hinges 406 running in perpendicular directions such that the assembly may be deformed as illustrated and/or in the perpendicular direction (e.g., shaped around a surface running from left to right across the page instead of around a surface that would be travel into the page as illustrated).

An assembly 400 is manufactured from a lower laminate 410 of a size large enough to include several thermoelectric modules 402. As discussed above, the lower laminate 410 may be a prepared laminate including an inner electrically conductive layer 416, a dielectric layer 420, and a thermally conductive layer 414. Portions of the inner electrically conductive layer 416 are removed (by etching, etc.) to form the conductive pads 422 for multiple thermoelectric modules 402 (as seen in FIG. 14). The lower laminate 410 is then scored (e.g., cut, etc.) to remove the dielectric layer 420 in the areas of the hinges 406. The lower laminate 410 is not, however, cut completely through. The thermally conductive layer 414 is left substantially intact (although the thermally conductive layer 414 may, if desired, be scored in the process as discussed above). Additionally, or alternatively, the lower laminate 410 (and more specifically, the thermally conductive layer 414) may be scored on the side of the thermally conductive layer 414 opposite the dielectric layer 420, as seen in FIG. 15.

Individual upper laminates 408 are prepared for each thermoelectric module 402. The upper laminates 408 may be individually constructed. Alternatively, and preferably, a sheet of prepared laminate material large enough for multiple upper laminates 408 is prepared in a manner similar to the method of preparing the lower laminate 410. The prepared laminate material is, however, completely cut through (instead of being simply scored) to produce the individual upper laminates 408. Thermoelectric elements 412 are mechanically and electrically connected (between the upper and lower laminates 408, 410) to the conductive pads 422. The individual thermoelectric modules 402 may be electrically connected (e.g., in parallel, in series, etc.) to complete one example articulated thermoelectric assembly. Additionally, or alternatively, the individual thermoelectric modules 402 may be provided independent (e.g., not electrically connected to one another) to permit a user to connect (or not) the thermoelectric modules 402 as desired for the user's purposes. The interface layer, if desired, may also be mechanically, and thermally, connected to the thermally conductive layer 414.

The thermoelectric assemblies 400 described herein may be any size, include any number of thermoelectric modules 402, and may be customizable by the user of the assembly. In one example embodiment, the prepared laminate for the lower substrate 410 measures eighteen inches by twenty-four inches. As discussed above, one example embodiment includes thirty-five thermoelectric modules 402 arranged in five rows of seven thermoelectric modules 402. More or fewer thermoelectric modules 402 may be included in more or fewer rows as desired without departing from the scope of this disclosure. For example, the assembly 400 may include forty-two thermoelectric modules 402 arranged in six rows of seven thermoelectric modules 402 or twenty-four thermoelectric modules 402 arranged in four rows of six thermoelectric modules 402, etc. Additionally, the user (particularly when the assembly 400 is provided without the thermoelectric modules 402 electrically connected to one another) may customize the size of the assembly 400 and, thus the number of thermoelectric modules 402. For example, a user may repeatedly bend the assembly 400 back and forth along one of the hinges 406 until the hinge fails (e.g., the thermally conductive layer 414 breaks) to separate a subassembly of a desired number of thermoelectric modules 402 in a desired configuration. For example, an assembly may be provided to a customer in “bulk” format if the pipe diameter is unknown at time of purchase. In this case, the customer may determine the number of modules needed to go around the customer's pipe, and then repeatedly bend the assembly at or along a scored area or hinge until it breaks to separate the desired number of modules. In exemplary embodiments that include gap filler, the customer may then cut the gap filler with a knife and install the modules. Additionally, or alternatively, an assembly in some embodiments may be supplied to a customer with jumper wires attached to carry current between adjacent modules, placing the electrically independent thermoelectric modules in series and providing a single wire pair to electrically drive the modules (in temperature control mode) or extract power from the modules (in power generation mode).

Additionally, in some embodiments, a heat sink and/or a fan may be coupled to the outer electrically conductive layer 418 of one or more upper laminates 408. Heat sinks and/or fans may improve thermal conduction of the assembly, reduce temperatures on and/or in the thermoelectric modules 402, reduce thermal stresses on the components of the assembly 400, etc.

The assembly 400 may be used for any suitable purpose (including heating/cooling and power generation discussed above). In particular, assembly 400 may be useful for generating power for sensors, data storage, transmitters, etc. in locations that are remote (e.g., where electrical wires are not available, etc.) and/or not easily accessible (e.g., where access is limited due to size restrictions and/or hazardous conditions, etc.). For example, the assembly 400 may be coupled around a fluid conduit located in the ceiling of a factory. The assembly 400 may generate power (in the manner discussed above) to power sensors and a transmitter to provide various sensed data (temperature, flow rate, etc.) without needing to physically access the pipe to retrieve the data, change batteries in a transmitter, etc.

In alternative exemplary embodiments, a thermoelectric assembly may include one or more thermoelectric modules having upper and lower laminates where at least one of the laminates also includes (e.g., supports, has mounted thereto, etc.) the electronics that control and drive the one or more thermoelectric modules. In these embodiments, for example, the thermoelectric module(s), power supply (which converts alternating current to direct current), temperature control board (which regulates the temperature) and controller circuitry may all be supported on, mounted to, and/or incorporated on the same board or substrate. This is unlike a typical thermoelectric assembly in which the power supply and temperature control board are mounted external or peripheral to the thermoelectric assembly.

Also in these exemplary embodiments, the board or substrate (on which the thermoelectric module(s) and the drive/control electronics are supported) may also take the place of upper or lower laminate of the thermoelectric module(s). That is, the board or substrate may be configured to function or operate as a lower laminate of a thermoelectric module as described above, for example, in regard to lower laminate 104 (FIGS. 1 and 2), lower laminate 204 (FIGS. 8 and 9), lower laminate 304 (FIG. 10), lower laminate 410 (FIG. 12), etc.

The exemplary embodiments of the thermoelectric assembly may include one or more thermoelectric modules substantially similar to any of the various exemplary embodiments disclosed herein, such as thermoelectric module 100 (FIGS. 1 and 2), thermoelectric module 200 (FIGS. 8 and 9), thermoelectric module 300 (FIG. 10), thermoelectric module 402 (FIG. 12), etc. except that the lower laminate thereof may also include (e.g., support, have mounted thereto, etc.) the electronics that control and drive the one or more thermoelectric modules. In these exemplary embodiments, a prefabricated laminate (e.g., TLAM™ circuit boards from Laird Technologies (St. Louis, Mo.), etc.) may be used for the thermoelectric module lower laminate (e.g., lower laminate 104 (FIGS. 1 and 2), lower laminate 204 (FIGS. 8 and 9), lower laminate 304 (FIG. 10), lower laminate 410 (FIG. 12), etc.). It should be appreciated, however, that laminates could be prefabricated to have any structures and/or combinations of structures as necessary for their desired uses within the scope of the present disclosure.

In an example use of a thermoelectric assembly, one or more objects or items to be cooled (e.g., plate, electronic device, etc.) may be thermally coupled (e.g., mounted, etc.) to the upper laminate(s) or substrate(s) of the thermoelectric module(s). In this particular example of a thermoelectric assembly, there are two thermoelectric modules sharing the same lower board or substrate to which is supported or mounted the drive/control electronics. This lower board or substrate is operable as the lower laminate for both thermoelectric modules as noted above. In addition, supporting the drive/control circuitry on this lower “hot side” substrate helps avoid (or at least reduces the extent that) heat from the drive/control circuitry being added to the cooling load.

A heat sink may be thermally coupled (e.g., mounted, etc.) to the side of the lower board or substrate opposite the thermoelectric modules. Accordingly, this exemplary arrangement may go from top-to-bottom as follows: object/item to be cooled, upper substrate/laminate, thermoelectric elements or dice, lower substrate/laminate, and heat sink. In operation, electrical current passing through the two thermoelectric modules may cause heat to be pumped from the upper laminates to the lower substrate. Naturally, this creates a warmer or hot side (the lower substrate) and a cooler side (the upper laminates) such that the one or more objects (e.g., plate, electronic device, sink, etc.) thermally coupled, mounted, exposed, etc. to the cooler side may subsequently be cooled (e.g., such that heat can be transferred from the object to the upper laminates, through the thermoelectric elements, to the lower laminate and then to the heat sink, etc.). This example is provided only for purpose of illustration, however, as various exemplary embodiments of thermoelectric modules disclosed herein may be used in a wide range of other applications, including as a heat pump, an electrical power generator, etc. in electrical devices such as, for example, computers, etc., as desired.

According to one example embodiment, a thermoelectric assembly includes a plurality of thermoelectric modules. Each of the thermoelectric modules includes a substantially rigid upper laminate, a substantially rigid lower laminate, and a plurality of thermoelectric elements disposed generally between the upper and lower laminates. The assembly also includes a substantially contiguous, substantially rigid, thermally conductive layer. The thermally conductive layer is mechanically connected to each of the thermoelectric modules and scored between adjacent thermoelectric modules to permit the thermally conductive layer to be consistently plastically deformed between adjacent thermoelectric modules.

According to another example embodiment, an articulated thermoelectric assembly includes a plurality of rigid upper laminates and a plurality of thermoelectric elements mechanically and electrically coupled to each upper laminate. The assembly includes an articulated lower substrate. The articulated lower substrate is mechanically and electrically coupled to the thermoelectric elements.

According to another example embodiment, a method of manufacturing an articulated thermoelectric assembly includes forming a plurality of groups of lower conductive pads on a lower substrate. Each group of conductive pads corresponds to a thermoelectric module. The lower substrate includes a dielectric layer and a thermally conductive layer on an opposite face of the dielectric layer from the conductive pads. The method includes scoring the lower substrate between adjacent groups of conductive pads and electrically and mechanically connecting a plurality of thermoelectric elements to each of the groups of lower conductive pads. The method also includes electrically and mechanically connecting a plurality of upper substrates to the thermoelectric elements, each of said upper substrates connected to the thermoelectric elements connected to a different one of said groups of lower conductive pads.

It should now be appreciated that various exemplary embodiments of thermoelectric modules of the present disclosure may, but need not, provide one or more various advantages over traditional ceramic based thermoelectric modules. For example, exemplary thermoelectric modules of the present disclosure may provide one or more of relatively low cost solutions to cooling operations; may reduce lead time for producing new circuit board designs; may allow for constructing thermoelectric modules having decreased thickness dimensions (e.g., down to about 0.04 inches (about 1 millimeter), etc.); may allow for quicker prototyping; may provide thermoelectric modules having improved strength; may provide improved thermal cycling reliability as the low mechanical stiffness of bare dielectric does not impart thermal expansion stresses to thermoelectric elements of the thermoelectric modules; may provide improved surfaces for coupling other thermal components to the thermoelectric modules; may allow greater varieties of bus bar configurations; and/or may allow for making a thermoelectric module with subcircuits such that the subcircuits can be connected together electrically in series, in parallel, or in an arbitrary series-parallel combination to cause a desired amount of current to pass through them even if only a single fixed DC power source (e.g., voltage, etc.) is provided (e.g., the same current may be passing through all of the subcircuits, but it can be adjusted in real time to pump a changing amount of heat with optimum efficiency such that advantages in both cooling and power generation may be provided, etc.).

Specific dimensions disclosed herein are example in nature and do not limit the scope of the present disclosure.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). Similarly, it is envisioned that disclosure of two or more ranges of values for a parameter (whether such ranges are nested, overlapping or distinct) subsume all possible combination of ranges for the value that might be claimed using endpoints of the disclosed ranges.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. A thermoelectric assembly comprising:
a plurality of thermoelectric modules, each of said thermoelectric modules including a substantially rigid upper laminate, a substantially rigid lower laminate, and a plurality of thermoelectric elements disposed generally between the upper and lower laminates;
a substantially contiguous, substantially rigid, thermally conductive layer, the thermally conductive layer mechanically connected to each of said thermoelectric modules and scored between adjacent thermoelectric modules to permit the thermally conductive layer to be consistently plastically deformed between adjacent thermoelectric modules.

2. The thermoelectric assembly of claim 1, further comprising an interface layer mechanically and thermally connected to the thermally conductive layer, the interface layer including a conformable, thermally conductive interface material.

3. The thermoelectric assembly of claim 1, wherein the lower laminate has a polymeric dielectric layer or a thermally enhanced polymeric dielectric layer and an electrically conductive layer coupled thereto.

4. The thermoelectric assembly of claim 1, wherein the upper laminate has a polymeric dielectric layer or a thermally enhanced polymeric dielectric layer and an electrically conductive layer coupled thereto.

5. The thermoelectric assembly of claim 1, wherein the upper laminate includes a ceramic dielectric layer and an electrically conductive layer coupled to the ceramic dielectric layer.

6. The thermoelectric assembly of claim 1, wherein the thermally conductive layer is laminated to the dielectric layer of the lower laminate of each of said thermoelectric modules.

7. The thermoelectric assembly of claim 1, wherein the thermally conductive layer is a metal.

8. The thermoelectric assembly of claim 1, wherein the thermally conductive layer comprises copper and/or aluminum.

9. The thermoelectric assembly of claim 1, wherein drive/control circuitry for the thermoelectric modules is mounted to at least one of the upper or lower laminates.

10. An articulated thermoelectric assembly comprising:
a plurality of rigid upper laminates;
a plurality of thermoelectric elements mechanically and electrically coupled to each upper laminate;
an articulated lower substrate mechanically and electrically coupled to the thermoelectric elements.

11. The articulated thermoelectric assembly of claim 10, wherein the lower substrate is articulated at positions substantially aligned with at least one edge of each of the upper laminates.

12. The articulated thermoelectric assembly of claim 10, wherein the lower substrate is articulated at positions substantially aligned with at least three edges of each of the upper laminates.

13. The articulated thermoelectric assembly of claim 10, wherein the lower substrate includes a plurality of hinges, at least one hinge located at each point of articulation of the articulated thermoelectric assembly.

14. The articulated thermoelectric assembly of claim 13, wherein:
the hinges are living hinges; and/or
the lower substrate includes a polymeric dielectric layer or a thermally enhanced polymeric dielectric layer.

15. The articulated thermoelectric assembly of claim 10, wherein:
the lower substrate is a laminate; and/or
drive/control circuitry for the thermoelectric elements is mounted to the lower substrate.

16. The articulated thermoelectric assembly of claim 10, wherein the lower substrate includes a dielectric layer, a first electrically conductive layer, and a second electrically conductive layer.

17. The articulated thermoelectric assembly of claim 16, wherein the first electrically conductive layer is at least partially removed to form electrically conductive pads for coupling with the plurality of thermoelectric elements.

18. The articulated thermoelectric assembly of claim 16, wherein portions of the dielectric layer and/or first electrically conductive layer are removed to create articulation points of the articulated thermoelectric assembly.

19. The articulated thermoelectric assembly of claim 10, further comprising a conformable, thermally conductive interface material interface mechanically and thermally connected to the lower substrate.

20. The articulated thermoelectric assembly of claim 10, wherein:
the assembly includes a plurality of articulation points; and
the assembly is substantially rigid between said articulation points.

21. A method of manufacturing an articulated thermoelectric assembly, the method comprising:
forming a plurality of groups of lower conductive pads on a lower substrate, each group of conductive pads corresponding to a thermoelectric module, the lower substrate including a dielectric layer and a thermally conductive layer on an opposite face of the dielectric layer from the conductive pads;
scoring the lower substrate between adjacent groups of conductive pads;
electrically and mechanically connecting a plurality of thermoelectric elements to each of the groups of lower conductive pads; and
electrically and mechanically connecting a plurality of upper substrates to the thermoelectric elements, each of said upper substrates connected to the thermoelectric elements connected to a different one of said groups of lower conductive pads.

22. The method of claim 21, further comprising:
electrically connecting the groups of lower conductive pads; and/or
coupling a conformable, thermally conductive interface material to the thermally conductive layer of the lower substrate; and/or
mounting drive/control circuitry for the thermoelectric elements to the first or second laminate.

23. The method of claim 21, wherein forming the plurality of groups of lower conductive pads includes removing portions of an electrically conductive layer of the lower substrate.

24. The method of claim 21, wherein scoring the lower substrate includes:
cutting a portion of the dielectric layer between adjacent groups of conductive pads; and/or
scoring the thermally conductive layer.

25. The method of claim 21, wherein:
the dielectric layer is a polymeric dielectric layer or a thermally enhanced polymeric dielectric layer; and/or
the thermally conductive layer is aluminum and/or copper.
